(19) United States
(12) Patent Application Publication
(10) Pub. No.: US 2021/0225193 A1
(43) Pub. Date: Jul. 22, 2021

(54) STRINGED INSTRUMENT TEACHING APPARATUS AND METHOD

(71) Applicants: Luigi Barosso, Essendon, Victoria 3040 (AU); Carla Barosso, Essendon, Victoria 3040 (AU)

(72) Inventor: Luigi Barosso, Essendon, Victoria 3040 (AU)

(21) Appl. No.: 17/055,622

(22) PCT Filed: May 17, 2019
(86) PCT No.: PCT/AU2019/050482

§ 371 Date: Nov. 16, 2020

(30) Foreign Application Priority Data
May 18, 2018 (AU) 2018203539

(51) Int. Cl. G09B 15/06; G10D 1/02; G10D 3/00; H03K 17/955

(52) U.S. Cl. CPC G09B 15/06; H03K 17/955; G10D 3/00; G10D 1/02

(57) ABSTRACT

The invention provides an apparatus (10) adapted to teach wrist position of a non-bowing arm (2, 3, 4, 5, 6) in a pupil playing a stringed instrument, and a method of monitoring correct wrist position. The apparatus (10) comprises a non-contact proximity sensor (22), a proximity information transmitter (23); related circuitry (20), a power source (21) and, in one embodiment, a housing (11, 12). The housing is attachable to the stringed instrument in an operating position; and the non-contact proximity sensor (22) is positioned so that when the housing (11, 12) is in the operating position, the non-contact proximity sensor (22) is sensitive at least to when an inner part (8) of the wrist or hand of the pupil comes closer to the non-contact proximity sensor than a threshold distance (D) associated with misalignment of the hand (2) and forearm (3) of the pupil.

### FIELD

The present invention relates to music instruction in stringed instruments, in particular but not limited to an apparatus and method for teaching correct wrist position of a non-bowing arm of a violin or viola pupil.

### BACKGROUND

Posture of the non-bowing arm of a violin player is an important part of correct violin playing technique, as it is understood in the violin teaching profession.

Referring to FIG. 1, an incorrect posture commonly adopted by violin pupils is illustrated, where the hand 2 and forearm 3 of the violin pupil are misaligned due to extension of the wrist 4, causing centrelines 5 and 6 of hand 2 and forearm 3 respectively to be disposed at an angle and wrist 4 being disposed near the neck and fingerboard 1 of the violin.

Referring to FIG. 2, a correct posture as shown with centrelines of hand 2 and forearm 3 in approximate straight alignment 7.

Known teaching aids involve attachments to the stringed instrument or attachments to the hand or arm of the pupil which provide a physical restriction to prevent extension of the wrist while playing. Such aids are bulky and difficult to store, and distracting and generally uncomfortable.

There is therefore a need to provide an improved apparatus to teach wrist position which overcomes one or more of the above-mentioned disadvantages, or provides a useful alternative to the solutions of the prior art.

### SUMMARY OF THE INVENTION

In accordance with a first broad aspect of the invention there is provided an apparatus adapted to teach wrist position of a non-bowing arm in a pupil playing a stringed instrument, the apparatus comprising:

a non-contact proximity sensor to sense non-contact proximity;

a proximity information transmitter adapted to provide the pupil or a teacher proximity information from the non-contact proximity sensor;

circuitry controlling the non-contact proximity sensor and the proximity information transmitter;

wherein:

at least the non-contact proximity sensor is attachable to the stringed instrument in an operating position so as to be sensitive at least to when an inner part of the wrist or hand of the pupil comes closer to the non-contact proximity sensor than a threshold distance associated with misalignment of a hand and forearm of the pupil.

In one embodiment, at least the non-contact proximity sensor is disposed in a housing sized so that the apparatus can remain attached to the stringed instrument while the stringed instrument is installed in a standard carrying case.

In one embodiment, the non-contact proximity sensor is a capacitive sensor. The capacitive sensor may be a flexible film sensor.

In one embodiment, the proximity information transmitter comprises an audio speaker which produces an alarm sound when the non-contact proximity sensor senses the threshold distance or closer of the wrist of the pupil.

In one embodiment, the circuitry comprises a wireless communicator and is adapted to communicate data concerning activation of the non-contact proximity sensor to a wireless connected smart phone, tablet or other computing device.

In one embodiment, the stringed instrument is a violin or viola, and the operating position may be a nose of the violin or viola.

In accordance with a second broad aspect of the invention there is provided method of monitoring wrist position of a non-bowing arm in a pupil playing a stringed instrument, the method comprising the steps of:

providing an apparatus of the first broad aspect of the invention;

attaching at least the non-contact proximity sensor to the stringed instrument in the operating position;

playing the stringed instrument; and

receiving the proximity information.

### BRIEF DESCRIPTION OF DRAWINGS

FIG. 1 shows a violin player with incorrect the non-bowing arm comprising an extended wrist;

FIG. 2 shows a violin player with the non-bowing arm with hand and forearm in substantial alignment;

FIG. 3 shows an apparatus according to an embodiment of the invention installed on a violin, with the pupil using correct posture;

FIG. 4 shows the apparatus of FIG. 3, with an audible alarm activated as a result of incorrect posture;

FIG. 5 shows an external perspective view of the apparatus of FIG. 3;

FIG. 6 shows internal componentry of the apparatus of FIG. 3.

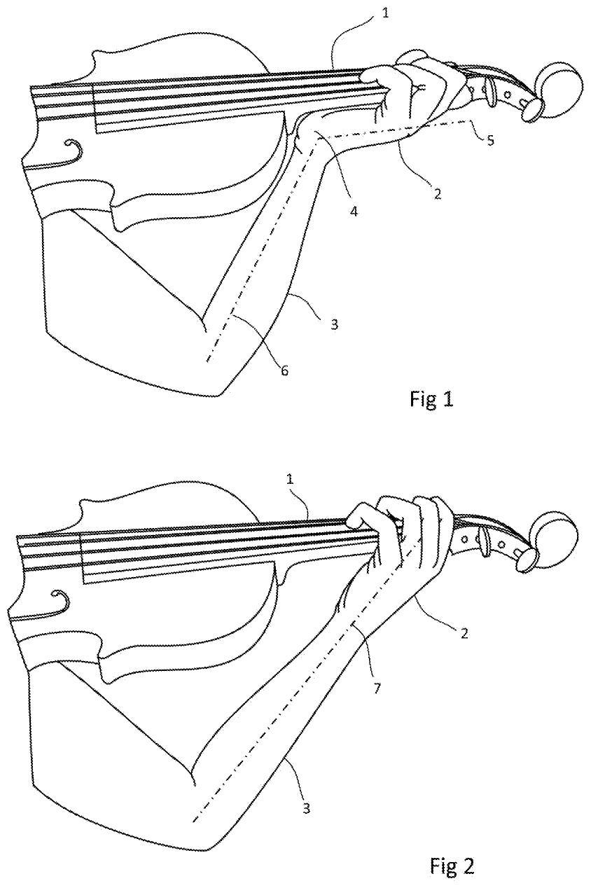

### DETAILED DESCRIPTION OF EMBODIMENTS

An embodiment of the current invention will now be described.

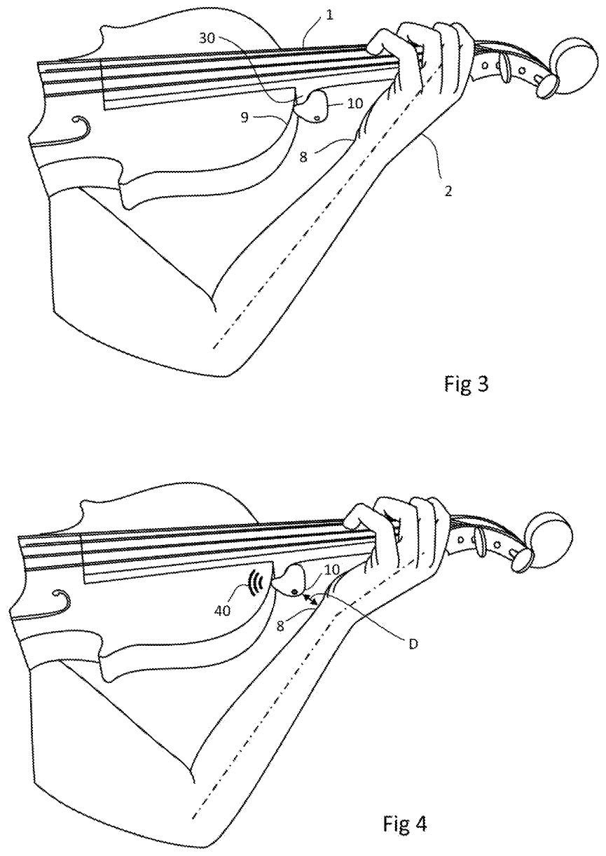

Referring first to FIG. 3, an embodiment apparatus 10 of the invention is shown installed around nose 30 of a violin, disposed under a junction between neck 1 and body 9 of the violin. An inner wrist surface 8 of the pupil is disposed at a sufficient distance from a non-contact proximity sensor inside apparatus 10, consequent on the correct posture, such that the apparatus does not issue an alarm signal.

Referring now to FIG. 4, inner wrist service 8 is shown approaching apparatus 10 a distance D as posture of the pupil worsens, at which point apparatus 10 issues an audible alarm signal 40 through a speaker.

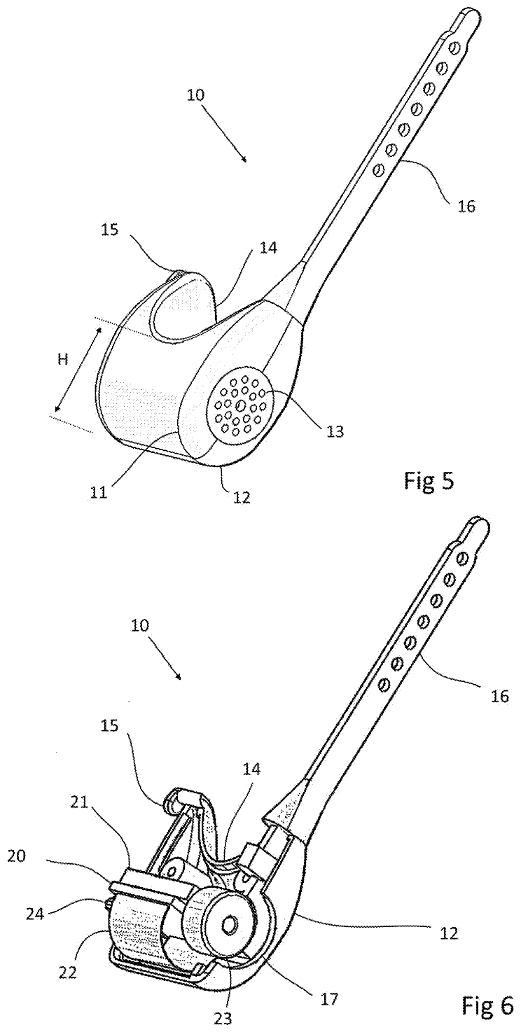

Referring now to FIG. 5, a perspective view of the assembled apparatus 10 is shown. Apparatus 10 comprises a housing consisting of first housing part 11 attached during assembly to second housing part 12. Perforated speaker outlet 13 is provided in a side of the housing to allow sound to escape the housing from a speaker. Moulded recess 14 is shaped to fit around nose 30 of the violin. Flexible strap 16 projects from one side of the housing and is adapted to fit around neck 1 between neck 1 and body 19 and to be attached through one of the attachment holes shown to catch 15 on an opposite side of the housing. External dimensions of the housing provided by first and second housing parts 11 and 12 provide a depth H of about 2 cm, which enables apparatus 10 to remain attached to the violin while in the standard storage case. Physical apparatuses of the prior art need to be much larger owing to the need to provide a physical contact with the wrist 8 and are more difficult to store.

Referring now to FIG. 6, apparatus 10 is shown with first housing part 11 absent before assembly, showing the inner componentry installed within second housing part 12. Apparatus 10 comprises audio speaker 23 disposed after assembly behind speaker outlet 13. Audio speaker 23 is electrically connected to circuitry on printed circuit board 20. Also connected to circuitry on printed circuit board 20 is non-contact proximity sensor 22 comprised of a flexible capacitive sensor bent into an arc to approximately follow an outer profile of first and second housing parts 11 and 12. A power source in this embodiment in form of a battery 21 provides power to the printed circuit board 20 and attached componentry. Battery 21 is preferably a rechargeable lithium ion battery. USB port 24 provides a charging connection for battery 21 and may also be used for external programming or adjustment of operating parameters on a microprocessor contained within the circuitry on printed circuit board 20.

An on-off switch (not shown) may also be provided to power the apparatus on or off. Sensitivity of non-contact proximity sensor 22 may be adjusted through micro-USB port 24 so that the triggering distance D is appropriate for each installation.

According to the embodiment described, audio speaker 23 is activated when non-contact proximity sensor 22 detects proximity of the inner wrist surface 8 less than the trigger distance D. This is one way of transmitting the proximity information to the pupil or teacher specified in the broadest aspect of the invention. Other embodiments may involve proximity information which is more complex and which can be transmitted to an external device and inspected after a teaching or learning session of the pupil. For example, the proximity information may include a time profile of measured proximity which is stored in a memory on printed circuit board 20 and transmitted to an external smart phone, tablet or other computing device after the lesson through USB port 24. Still further embodiments may involve a proximity information transmitter which is in the form of a warning light which illuminates a constant or flashing light when non-contact proximity sensor 22 detects proximity.

The inventor has thus provided an improved apparatus for correcting wrist posture that is not noticed by the pupil until wrist posture becomes incorrect, unlike physical restraints of the prior art.

Persons skilled in the art will also appreciate that many variations may be made to the invention without departing from the scope of the invention, which is determined from the broadest scope and claims.

For example, while the embodiment above is programmed and communicated through USB port 24, other interfaces including Bluetooth or Wi-Fi interfaces are within the scope of the invention providing that power requirements and physical space within the apparatus can be accommodated. As will be appreciated by a person skilled in the art, electronic componentry forming part of the circuitry on printed circuit board 20 is readily available and easily configurable to provide the functionalities of the invention and extended functionalities for communication purposes with external devices. As will also be appreciated by person skilled in the art, apps can be written to process the proximity data store by the device communicated through USB port 24 or otherwise through a wireless link, and to display the information in a useful manner to the teacher or pupil. For example, if a microphone is also provided within the apparatus, a recording of the playing could be stored alongside the time profile of proximity information, enabling the pupil to understand where in the music a tendency to move outside of ideal posture is observed.

Further, while the non-contact proximity sensor described in the embodiment above is a capacitive sensor which is well adapted to sensing skin, other sensors able to appropriately measure proximity of a wrist or hand such as lasers are within the scope of the invention, including sensors which may require the pupil to position a metal or other substance on the inner surface 8 of the wrist or hand. Accordingly, the term “non-contact proximity sensor” in the claims encompasses such other non-contact sensors appropriate to measure proximity of a wrist or hand, except where the context requires otherwise.

Further also, while the embodiment described above comprises a housing containing the non-contact proximity sensor, the proximity information transmitter, the circuitry and a power source, other embodiments are within the scope of the invention not containing a housing or containing more than one housing connected by wires or communication links.

Further also, while the positioning of the embodiment described in the diagrams typically results in the wrist of the player coming into closest proximity with the non-contact proximity sensor, other positions of the non-contact proximity sensor or playing positions may result in the hand of the player (such as the palm) coming into closest proximity.

In the claims which follow and in the preceding description of the invention, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention. Further, any method steps recited in the claims are not necessarily intended to be performed temporally in the sequence written, or to be performed without pause once started, unless the context requires it.

It is to be understood that, if any prior art publication is referred to herein, such reference does not constitute an admission that the publication forms a part of the common general knowledge in the art, in Australia or any other country.

1: An apparatus adapted to teach wrist position of a non-bowing arm in a pupil playing a stringed instrument, the apparatus comprising:
a non-contact proximity sensor to sense proximity;
a proximity information transmitter adapted to provide the pupil or a teacher proximity information from the non-contact proximity sensor;
circuitry controlling the non-contact proximity sensor and the proximity information transmitter; and
wherein the non-contact proximity sensor is attachable to the stringed instrument in an operating position so as to be sensitive at least to when an inner part of the wrist or hand of the pupil comes closer to the non-contact proximity sensor than a threshold distance associated with misalignment of the hand and forearm of the pupil.

2: The apparatus of claim 1, wherein at least the non-contact proximity sensor is disposed in a housing sized so that the apparatus can remain attached to the stringed instrument while the stringed instrument is installed in a standard carrying case.

3: The apparatus of claim 1, wherein the non-contact proximity sensor is a capacitive sensor.

4: The apparatus of claim 3, wherein the capacitive sensor is a flexible film sensor.

5: The apparatus of claim 1, wherein the proximity information transmitter comprises an audio speaker which produces an alarm sound when the non-contact proximity sensor senses the threshold distance or closer of the wrist of the pupil.

6: The apparatus of claim 1 wherein the circuitry comprises a wireless communicator and is adapted to communicate data concerning activation of the non-contact proximity sensor to a wireless connected smart phone, tablet or other computing device.

7: The apparatus of claim 1, wherein the stringed instrument is a violin or viola.

8: The apparatus of claim 7, wherein the operating position is a nose of the violin or viola.

9: A method of monitoring wrist position of a non-bowing arm in a pupil playing the stringed instrument of claim 1, the method comprising the steps of:
providing the apparatus as claimed in claim 1;
attaching the non-contact proximity sensor to the stringed instrument in the operating position;
playing the stringed instrument; and
receiving the proximity information.
